(19) United States
(12) Patent Application Publication
(10) Pub. No.: US 2024/0421727 A1
(43) Pub. Date: Dec. 19, 2024

(54) CONTROL DEVICE THAT CONTROLS VIBRATION DEVICE, AND METHOD OF CONTROLLING VIBRATION DEVICE

(71) Applicant: Murata Manufacturing Co., Ltd., Nagaokakyo-shi (JP)

(72) Inventors: Takaaki MORI, Nagaokakyo-shi (JP); Masaaki TAKATA, Nagaokakyo-shi (JP); Noritaka KISHI, Nagaokakyo-shi (JP)

(21) Appl. No.: 18/819,141

(22) Filed: Aug. 29, 2024

Related U.S. Application Data
(63) Continuation of application No. PCT/JP2022/042058, filed on Nov. 11, 2022.

(30) Foreign Application Priority Data
Mar. 31, 2022 (JP) 2022-059993

(51) Int. Cl. H02N 2/14; H02N 2/16

(52) U.S. Cl. CPC H02N 2/145; H02N 2/163

(57) ABSTRACT

The present disclosure relates to a method of controlling a vibration device including a piezoelectric element via a control device. The method includes changing a frequency of a drive signal for driving the piezoelectric element, measuring a value related to an impedance of the piezoelectric element, and determining a driving frequency for driving the piezoelectric element based on a change in the measured value related to the impedance of the piezoelectric element. The changing of the frequency of the drive signal includes changing a clock width such that a clock width of a first portion of clocks among a plurality of clocks included in the drive signal and a clock width of a second portion of clocks among a plurality of clocks are different from each other.

### CROSS REFERENCE TO RELATED APPLICATIONS

This application is a continuation of International Application No. PCT/JP2022/042058, filed Nov. 11, 2022, which claims priority to Japanese Patent Application No. 2022-059993, filed Mar. 31, 2022, the entire contents of each of which are hereby incorporated in their entirety.

### TECHNICAL FIELD

The present disclosure is directed to a control device that controls a vibration device and a method of controlling a vibration device.

### BACKGROUND

A resonant frequency of a piezoelectric element provided in or on a vibration device or the like is changed by various factors. For example, Japanese Unexamined Patent Application Publication No. 8-126357 (the “'357 Application”) discloses a piezoelectric motor drive circuit that controls and drives a piezoelectric element such that an alternating current flowing through the piezoelectric element is substantially constant even when resonant frequency characteristics of the piezoelectric element are changed due to a fluctuation in ambient temperature or the like.

In recent years, in a vibration device including a piezoelectric element, it is required to appropriately control a driving frequency for driving the piezoelectric element.

### SUMMARY OF INVENTION

Therefore, it is an object of the present disclosure to provide a control device that controls a vibration device that can appropriately control a driving frequency for driving a piezoelectric element, and a method of controlling the vibration device.

According to an exemplary aspect of the present disclosure, a method is provided for controlling a vibration device including a piezoelectric element via a control device. In this aspect, the method includes changing a frequency of a drive signal for driving the piezoelectric element, measuring a value related to an impedance of the piezoelectric element, and determining a driving frequency for driving the piezoelectric element based on the measured value related to the impedance of the piezoelectric element. The changing of the frequency of the drive signal includes changing a clock width such that a clock width of some clocks among a plurality of clocks included in the drive signal and a clock width of other clocks are different from each other.

Further, according to another exemplary aspect of the present disclosure, a control device is provided that controls a vibration device including a piezoelectric element. In this aspect, the control device includes a processor, and a memory that stores a command executed by the processor, in which the command includes changing a frequency of a drive signal for driving the piezoelectric element from the processor, measuring a value related to an impedance of the piezoelectric element, and determining a driving frequency for driving the piezoelectric element based on the measured value related to the impedance of the piezoelectric element. Moreover, the changing of the frequency of the drive signal includes changing a clock width such that a clock width of some clocks among a plurality of clocks included in the drive signal and a clock width of other clocks are different from each other.

According to the control device of the vibration device and the control method of the vibration device according to the exemplary aspects of the present disclosure, the driving frequency for driving the piezoelectric element can be appropriately controlled.

### BRIEF DESCRIPTION OF DRAWINGS

In the descriptions that follow, like parts are marked throughout the specification and drawings with the same numerals, respectively. The drawings are not necessarily drawn to scale and certain drawings may be illustrated in exaggerated or generalized form in the interest of clarity and conciseness. The disclosure itself, however, as well as a mode of use, further features and advances thereof, will be understood by reference to the following detailed description of illustrative implementations of the disclosure when read in conjunction with reference to the accompanying drawings, wherein:

FIG. 1 is a perspective view for describing a configuration of an imaging unit in accordance with aspects of the present disclosure;

FIG. 2 is a schematic cross-sectional view illustrating a cross-sectional configuration of the imaging unit in accordance with aspects of the present disclosure;

FIG. 3 is a schematic cross-sectional view illustrating a cross-sectional configuration of a vibration device in accordance with aspects of the present disclosure;

FIG. 4 is an exploded perspective view illustrating each component of the vibration device in accordance with aspects of the present disclosure;

FIG. 5 is a block diagram describing a configuration of a control device that controls the vibration device in accordance with aspects of the present disclosure;

FIG. 6 is a transition diagram of an operation mode for describing an operation of the control device that controls the vibration device in accordance with aspects of the present disclosure;

FIG. 7 is a flowchart describing an operation of the control device that controls the vibration device in accordance with aspects of the present disclosure;

FIG. 8 illustrates a relationship between a resonant frequency and an impedance of a piezoelectric element when an effective voltage is constant in accordance with aspects of the present disclosure;

FIG. 9A illustrates a relationship between a resonant frequency and an impedance of the piezoelectric element when an effective voltage is changed in accordance with aspects of the present disclosure;

FIG. 9B illustrates a relationship between a resonant frequency and an impedance of the piezoelectric element when an effective voltage is changed in accordance with aspects of the present disclosure;

FIG. 10 is a flowchart describing an operation of a control device that controls a vibration device in accordance with aspects of the present disclosure;

FIG. 11 is a flowchart describing an operation of a control device that controls a vibration device in accordance with aspects of the present disclosure;

FIG. 12 is a flowchart describing an operation of a control device that controls a vibration device in accordance with aspects of the present disclosure;

FIG. 13 illustrates an example of a plurality of clocks included in a drive signal in which a clock width is changed, in a method of controlling the vibration device in accordance with aspects of the present disclosure;

FIG. 14 illustrates a relationship between a frequency of the drive signal and a resonant frequency in a graph illustrating a relationship between a resonant frequency and an impedance of the piezoelectric element in accordance with aspects of the present disclosure;

FIG. 15 is a flowchart describing an operation of a control device that controls a vibration device in accordance with aspects of the present disclosure; and

FIG. 16 illustrates an example of a plurality of clocks included in a drive signal in which a clock width is changed, in a method of controlling a vibration device in accordance with aspects of the present disclosure.

### DETAILED DESCRIPTION

Hereinbelow, aspects of the present disclosure will be described. In a following description of the drawings, the same or similar components will be represented with use of the same or similar reference characters. The drawings are exemplary, sizes or shapes of portions are schematic, and technical scope of the present disclosure should not be understood with limitation to the aspects.

In an exemplary aspect, an imaging unit is provided at a front part or a rear part of a vehicle to control a safety device or to perform automatic driving control by using an image captured by the imaging unit. Since such an imaging unit is often provided outside the vehicle, a foreign matter such as raindrop, mud, and dust may adhere to a light-transmitting body such as a lens or a protective glass that covers the outside. When the foreign matter adheres to the light-transmitting body, the foreign matter adhering to the image captured by the imaging unit is reflected, and a clear image cannot be obtained.

Therefore, a vibration device that vibrates a light-transmitting body to remove the foreign matter has been developed. Such a vibration device vibrates the light-transmitting body by using, for example, a piezoelectric element, but a resonant frequency of the piezoelectric element is changed by various factors such as heat generated by the piezoelectric element and a foreign matter adhering to the light-transmitting body. Therefore, when the driving frequency for driving the piezoelectric element is not appropriately controlled, the light-transmitting body cannot be efficiently vibrated.

For example, a control device that searches for a resonant frequency of the piezoelectric element has been developed to control a driving frequency for driving the piezoelectric element. As the search performance of the resonant frequency of the piezoelectric element is higher, the driving frequency of the piezoelectric element can be appropriately controlled. For example, as one method of improving the search performance of the resonant frequency, a method of improving the performance of a processor of the control device is considered. However, when the performance of the processor of the control device is improved, there is a problem in that manufacturing cost is increased and the installation area of the processor is increased.

According to an exemplary aspect of the present disclosure, a method is provided of controlling a vibration device including a piezoelectric element via a control device. In this aspect, the method includes changing a frequency of a drive signal for driving the piezoelectric element, measuring a value related to an impedance of the piezoelectric element, and determining a driving frequency for driving the piezoelectric element based on the measured value related to the impedance of the piezoelectric element. Moreover, the changing of the frequency of the drive signal includes changing a clock width such that a clock width of some clocks among a plurality of clocks included in the drive signal and a clock width of other clocks are different from each other.

With such a configuration, the driving frequency for driving the piezoelectric element can be appropriately controlled. In addition, the manufacturing cost can be reduced.

In the method, some clocks (a first portion of clocks) may be periodically located in the plurality of clocks.

With such a configuration, the driving frequency of the piezoelectric element can be appropriately controlled.

In the method, some clocks may be located at equal intervals in the plurality of clocks.

With such a configuration, the driving frequency of the piezoelectric element can be appropriately controlled.

In the method, among the plurality of clocks, the clock width of some clocks may be changed to 0.5 times or more and less than one time or to be greater than one time and 1.5 times or less the clock width of the other clocks (a second portion of clocks).

With such a configuration, the driving frequency of the piezoelectric element can be more appropriately controlled.

In the method, a clock width of a clock of 0.1% or more and 99.9% or less among the plurality of clocks may be changed.

With such a configuration, the driving frequency of the piezoelectric element can be appropriately controlled.

In the method, the value related to the impedance may be an impedance value, and the determining of the driving frequency may include determining whether or not the value related to the impedance is equal to or less than a predetermined threshold value, and determining a frequency of the drive signal when it is determined that the value related to the impedance is equal to or less than the predetermined threshold value as the driving frequency.

With such a configuration, the driving frequency of the piezoelectric element can be appropriately controlled.

The method may further include changing the clock width, in a case where the driving frequency cannot be determined based on the value related to the impedance measured after the clock width is changed, in the determining of the driving frequency.

With such a configuration, the driving frequency of the piezoelectric element can be appropriately controlled.

In the method, the changing of the frequency of the drive signal may include changing the frequency with clock widths of the plurality of clocks being kept constant, the measuring of the value related to the impedance may include measuring the value related to the impedance while changing the frequency with the clock width being kept constant, and in the determining of the driving frequency, in a case where the driving frequency cannot be determined based on the value related to the impedance measured while changing the frequency with the clock width being kept constant, changing the clock width may be performed.

With such a configuration, the driving frequency of the piezoelectric element can be more appropriately controlled.

According to an aspect of the present disclosure, a control device is provided that controls a vibration device including a piezoelectric element. In this aspect, the control device includes a processor, and a memory that stores a command executed by the processor, in which the command includes changing a frequency of a drive signal transmitted from the processor to the piezoelectric element, measuring a value related to an impedance of the piezoelectric element, and determining a driving frequency for driving the piezoelectric element based on the measured value related to the impedance of the piezoelectric element. Moreover, the changing of the frequency of the drive signal includes changing a clock width such that a clock width of some clocks among a plurality of clocks included in the drive signal and a clock width of the other clocks are different from each other.

With such a configuration, the driving frequency of the piezoelectric element can be appropriately controlled. In addition, the manufacturing cost can be reduced.

In the control device, some clocks may be periodically located in the plurality of clocks.

With such a configuration, the driving frequency of the piezoelectric element can be appropriately controlled.

In the control device, some clocks may be located at equal intervals in the plurality of clocks.

With such a configuration, the driving frequency of the piezoelectric element can be appropriately controlled.

In the control device, among the plurality of clocks, the clock width of some clocks may be changed to 0.5 times or more and less than one time or to be greater than one time and 1.5 times or less the clock width of the other clocks.

With such a configuration, the driving frequency of the piezoelectric element can be appropriately controlled.

In the control device, a clock width of a clock of 0.1% or more and 99.9% or less among the plurality of clocks may be changed.

With such a configuration, the driving frequency of the piezoelectric element can be appropriately controlled.

In an exemplary aspect, the value related to the impedance may be an impedance value, and the determining of the driving frequency may include determining whether or not the value related to the impedance is equal to or less than a predetermined threshold value, and determining a frequency of the drive signal when it is determined that the value related to the impedance is equal to or less than the predetermined threshold value as the driving frequency.

With such a configuration, the driving frequency of the piezoelectric element can be appropriately controlled.

The command may include further changing the clock width, in a case where the driving frequency cannot be determined based on the value related to the impedance measured after the clock width is changed, in the step of determining the driving frequency.

With such a configuration, the driving frequency of the piezoelectric element can be appropriately controlled.

The changing of the frequency of the drive signal may include changing the frequency with clock widths of the plurality of clocks being kept constant, the step of measuring the value related to the impedance may include measuring the value related to the impedance while changing the frequency with the clock width being kept constant, and in the determining of the driving frequency, in a case where the driving frequency cannot be determined based on the value related to the impedance measured while changing the frequency with the clock width being kept constant, changing the clock width may be performed.

With such a configuration, the driving frequency of the piezoelectric element can be appropriately controlled.

Hereinafter, exemplary aspects of the present disclosure will be described with reference to the accompanying drawings. In addition, in each drawing, each element is exaggerated for easy description.

In the present specification, it is noted that terms such as “first” and “second” are used for description only and are not to be understood as expressing or implying relative importance or the order of technical features. The features limited by “first” and “second” express or imply that one or more of the features are included.

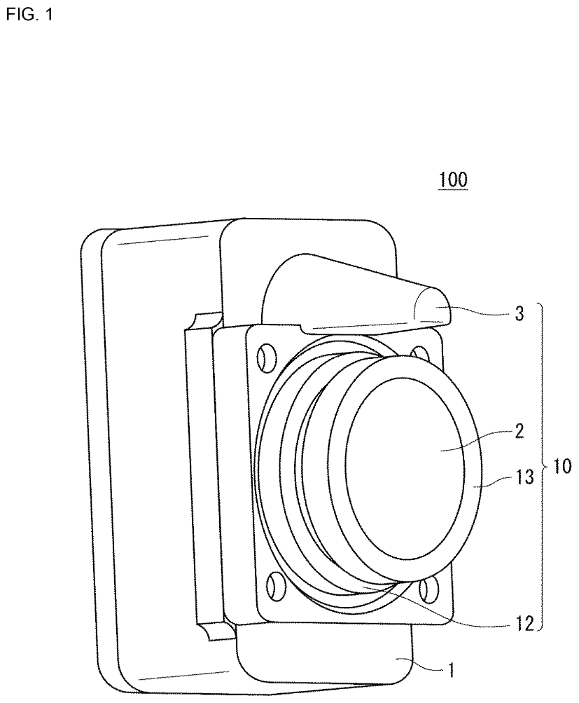

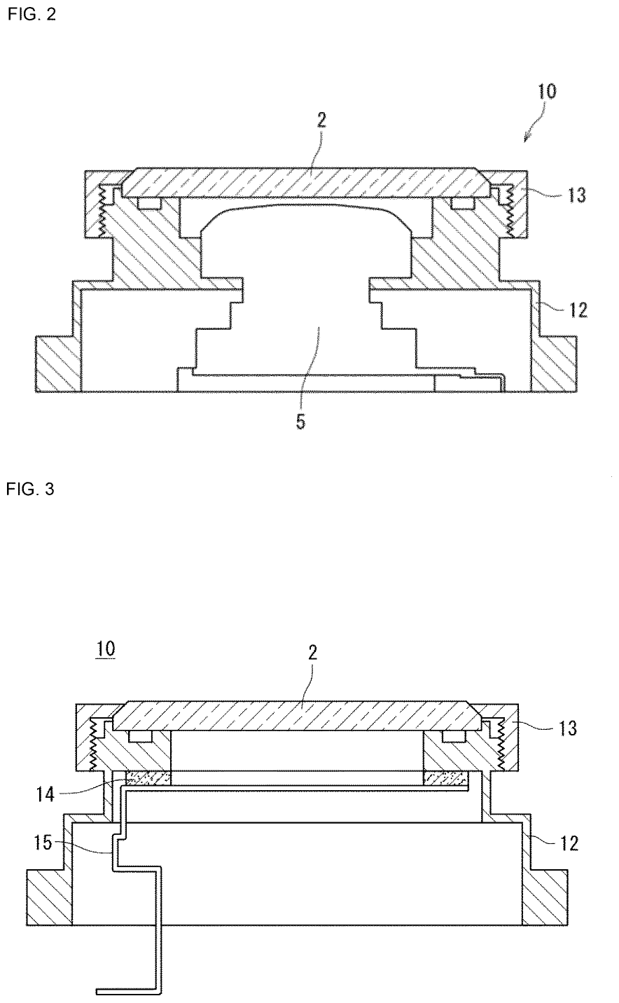

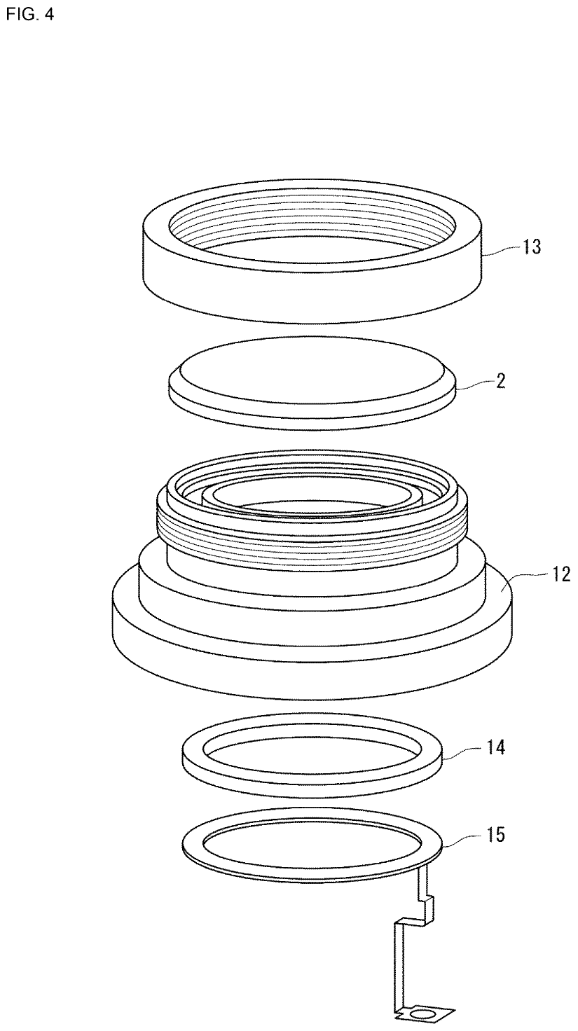

Hereinafter, an imaging unit provided with a vibration device according to an aspect will be described with reference to the accompanying drawings. FIG. 1 is a perspective view for describing a configuration of an imaging unit according to an aspect. FIG. 2 is a schematic cross-sectional view illustrating a cross-sectional configuration of the imaging unit according to an aspect. FIG. 3 is a schematic cross-sectional view illustrating a cross-sectional configuration of a vibration device according to an aspect. FIG. 4 is an exploded perspective view illustrating each component of the vibration device according to an aspect.

As illustrated in FIGS. 1 and 2, an imaging unit 100 includes a housing 1, a vibration device 10, and an imaging device 5.

As illustrated in FIGS. 1 and 2, the housing 1 includes the imaging device 5. The housing 1 exposes a part of the vibration device 10. For example, the material of the housing 1 is a resin.

As illustrated in FIGS. 3 and 4, the vibration device 10 includes a light-transmitting body 2, a vibration body 12 that vibrates the light-transmitting body 2, and a retainer 13 that supports an outer peripheral edge of the light-transmitting body 2. As illustrated in FIG. 1, in the vibration device 10, the light-transmitting body 2, the retainer 13, and a part of the vibration body 12 are exposed from a hole provided in the housing 1. The vibration device 10 is configured to remove a foreign matter adhering to the light-transmitting body 2 by vibrating the light-transmitting body 2.

The light-transmitting body 2 is disposed on the front surface of the imaging device 5. The vibration device 10 is configured to remove the foreign matter adhering to the light-transmitting body 2. The light-transmitting body 2 has translucency through which energy rays or light having a wavelength detected by the imaging device 5 is transmitted. In addition, the light-transmitting body 2 may be a lens having a light collecting property.

The vibration body 12 vibrates the light-transmitting body 2 to remove the adhered foreign matter. As illustrated in FIG. 4, the vibration body 12 has a cylindrical shape. A hollow circular, that is, annular, piezoelectric element 14 is provided, for example, on a surface of the vibration body 12 opposite to a surface in contact with the light-transmitting body 2. Furthermore, in the piezoelectric element 14, wiring 15 having a hollow circular, that is, annular, electrode is provided on a surface opposite to the surface in contact with the vibration body 12. By applying a voltage to the wiring 15 to vibrate the piezoelectric element 14 in the penetration direction of the cylindrical vibration body 12, the light-transmitting body 2 can be vibrated in the penetration direction of the vibration body 12 with the vibration body 12 interposed therebetween.

It is noted that the position of the piezoelectric element 14 provided in the vibration body 12 is not limited to a position illustrated in FIG. 3.

The retainer 13 is connected to the vibration body 12. Each of the retainer 13 and the vibration body 12 is subjected to screwing processing, and screwing processed portions of the retainer 13 and the vibration body 12 are fitted and connected to each other. The material of the retainer 13 may be, for example, not only metal such as stainless steel, aluminum, iron, titanium, and duralumin, but also plastic.

The vibration device 10 may further have a configuration of ejecting a cleaning solution (e.g., cleaning medium) onto the light-transmitting body 2 to remove the foreign matter adhering to the light-transmitting body 2. For example, as illustrated in FIG. 1, a cleaning nozzle 3 that ejects the cleaning solution onto the light-transmitting body 2 ejects the cleaning solution onto the light-transmitting body 2 to remove the adhered foreign matter.

The imaging device 5 is configured to image an imaging target outside the vibration device 10 through the light-transmitting body 2 of the vibration device 10. The imaging device 5 incorporates, for example, an optical element, an imaging element, a sensor component, and the like.

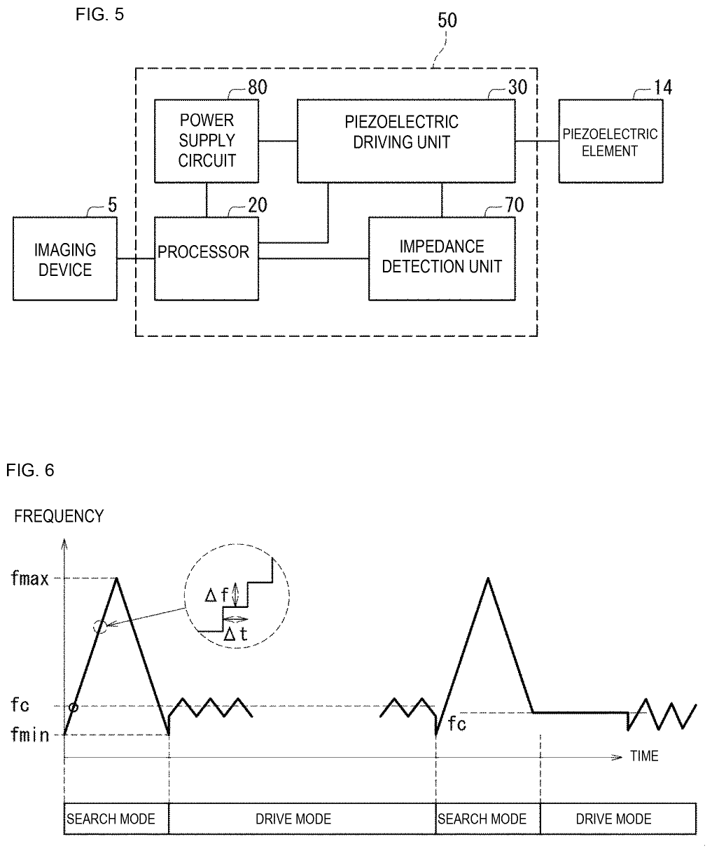

Next, a configuration of the control device 50 that controls the vibration device 10 will be described with reference to the drawings. FIG. 5 is a block diagram describing a configuration of a control device that is configured to control the vibration device according to an aspect of the present disclosure.

The control device 50 includes a processor 20, a piezoelectric driving unit 30, an impedance detection unit 70, and a power supply circuit 80. The processor 20 is a control unit that processes the imaging signal from the imaging device 5 and that supplies a control signal to the piezoelectric driving unit 30.

In an exemplary aspect, the processor 20 is provided with a central processing unit (CPU) as a control center, a read only memory (ROM) in which a program for the CPU to operate, control data, and the like are stored, a random access memory (RAM) that functions as a work area of the CPU, an input/output interface for maintaining the matching property of signals with peripheral devices, and the like. The processor 20 may also be a microcomputer, a micro-processing unit (MPU), a graphics processing unit (GPU), a digital signal processor (DSP), a field programmable gate array (FPGA), or an application specific integrated circuit (ASIC).

The piezoelectric driving unit 30 is configured to generate a drive signal according to a driving voltage and a frequency for driving the piezoelectric element 14 in response to a control signal from the processor 20.

The piezoelectric element 14 is configured to vibrate when the drive signal generated via the piezoelectric driving unit 30 is applied. The vibration body 12 and the light-transmitting body 2 vibrate due to the vibration of the piezoelectric element 14, and the foreign matter is removed. As a material for forming the piezoelectric element 14, for example, appropriate piezoelectric ceramics such as barium titanate (BaTiO₃), lead zirconate titanate (PZT: PbTiO₃·PbZrO₃), lead titanate (PbTiO₃), lead metaniobate (PbNb₂O₆), bismuth titanate (Bi₄Ti₃O₁₂), and (K, Na)NbO₃; or appropriate piezoelectric single crystals such as LiTaO₃ and LiNbO₃ can be used.

The impedance detection unit 70 is configured to monitor a value related to the impedance of the piezoelectric driving unit 30 in a case where the piezoelectric element 14 is vibrated. The value related to the impedance is, for example, a current, an impedance, and the like.

The power supply circuit 80 is configured to output a signal of the alternating current. For example, the effective voltage of the power supply circuit 80 is 0 V or more and 70 V or less.

The piezoelectric driving unit 30 and the impedance detection unit 70 can be achieved by, for example, an electronic circuit. The functions of the piezoelectric driving unit 30 and the impedance detection unit 70 may be configured by using only hardware or may be achieved by using a combination of hardware and software. The piezoelectric driving unit 30 and the impedance detection unit 70 may achieve a predetermined function by reading out data or a program stored in a storage unit such as a memory, and performing various types of arithmetic processing.

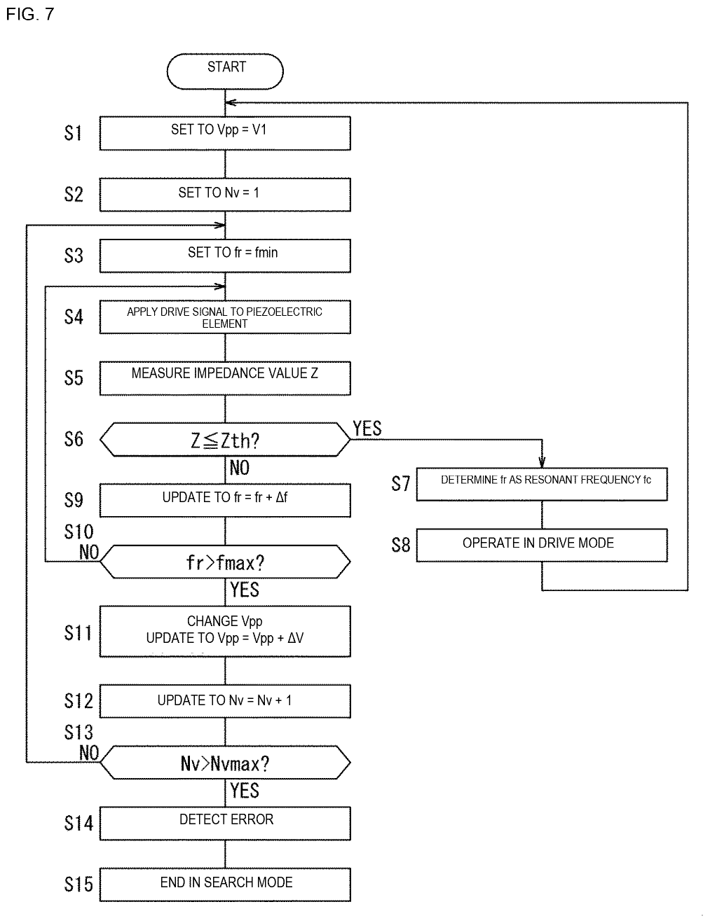

Next, the operation of the control device 50 will be described with reference to a transition diagram and a flowchart. FIG. 6 is a transition diagram of an operation mode for describing an operation of the control device that controls the vibration device according to an aspect of the present disclosure. FIG. 7 is a flowchart describing an operation of the control device that controls the vibration device according to an aspect of the present disclosure.

As illustrated in FIG. 6, the control device 50 drives the piezoelectric element 14 in a search mode and a drive mode. The search mode causes the piezoelectric element 14 to vibrate to determine a resonant frequency fc of the piezoelectric element 14. The drive mode causes the vibration body 12 to vibrate at the resonant frequency fc determined in the search mode, and causes the piezoelectric element 14 to vibrate to remove the foreign matter adhering to the surface of the light-transmitting body 2. The search mode and the drive mode are alternately performed. Hereinafter, detailed steps of the search mode will be described.

The search mode in accordance with an aspect of the present disclosure includes a first search step and a second search step. In the first search step, a frequency fr of the drive signal is swept between fmin and fmax to search for the resonant frequency fc of the piezoelectric element 14. The term “sweep” refers to changing the frequency fr stepwise over time. For example, the term “sweep” refers to increasing the frequency fr by Δf every time Δt is elapsed. In addition, fmin is the minimum value of the frequency fr of the drive signal, and fmax is the maximum value of the frequency fr of the drive signal. The second search step is performed in a case where the resonant frequency fc cannot be searched for in the first search step. In the second search step, the resonant frequency fc is searched for by changing a driving voltage Vpp applied to the piezoelectric element 14.

First, the control device 50 sets the driving voltage Vpp of the drive signal for driving the piezoelectric element 14 to a voltage V1 (step S1), and sets the number of update times Nv of the driving voltage Vpp to 1 (step S2). For example, the driving voltage Vpp is an alternating voltage. For example, the effective voltage of the voltage V1 is 0 V or more and 70 V or less.

Next, the control device 50 sets the frequency fr of the drive signal to the frequency fmin (step S3). For example, the frequency fmin is 20 kHz or more and 1 MHz or less.

Next, the control device 50 applies the driving voltage Vpp set in step S1 and the drive signal of the frequency fr set in step S3 to the piezoelectric element 14 (step S4).

Next, the control device 50 measures the impedance value Z of the piezoelectric element 14 at the frequency fr of the drive signal (step S5).

Next, the control device 50 determines whether or not (when) the measured impedance value Z is equal to or less than a predetermined threshold value Zth (step S6). For example, the threshold value Zth is greater than 0Ω and 1 kΩ or less.

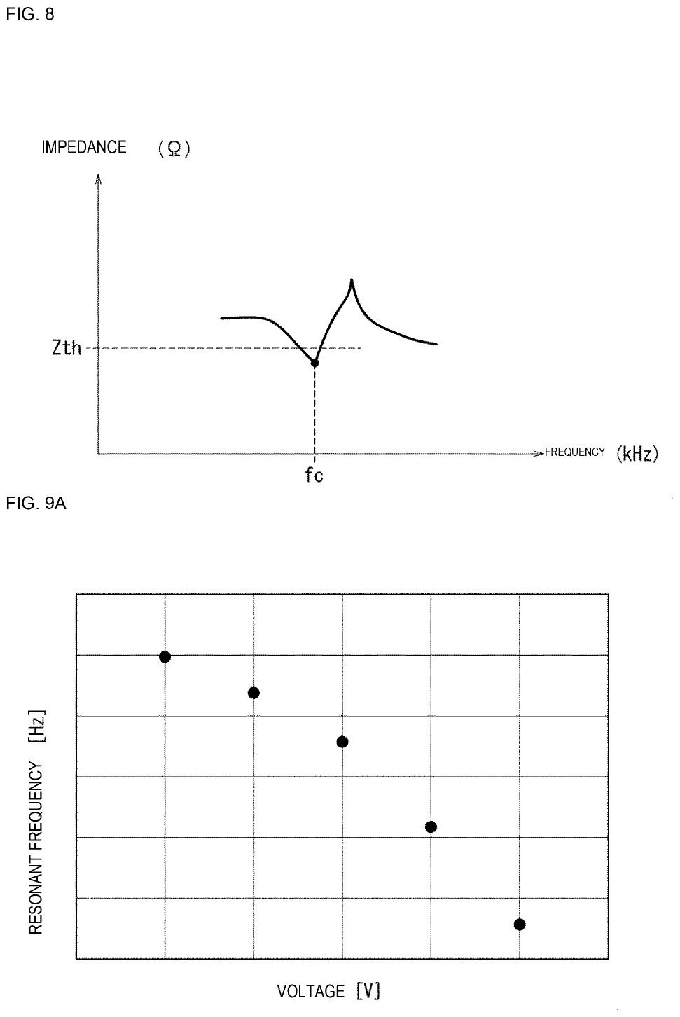

Here, a relationship between the impedance and the resonant frequency of the piezoelectric element 14 will be described with reference to FIG. 8. FIG. 8 illustrates a relationship between the resonant frequency fc and the impedance Z of the piezoelectric element 14 when the driving voltage Vpp is constant. In FIG. 8, the horizontal axis represents the frequency (kHz), and the vertical axis represents the impedance (Ω). In the graph illustrated in FIG. 8, the frequency of the portion where the impedance is rapidly changed is the resonant frequency fc of the piezoelectric element 14. Therefore, when the frequency fr of the drive signal matches the resonant frequency fc of the piezoelectric element 14 or is close to the resonant frequency fc of the piezoelectric element 14, the impedance value Z of the piezoelectric element 14 to be measured is equal to or less than the threshold value Zth.

Therefore, when it is determined that the impedance value Z measured in step S5 is equal to or less than the threshold value Zth, the control device 50 determines the frequency fr of the drive signal as the resonant frequency fc of the piezoelectric element 14 (step S7).

After step S5, the control device 50 operates in a drive mode of removing the foreign matter adhering to the light-transmitting body 2 by causing the piezoelectric element 14 to vibrate at the resonant frequency fc (step S8). Specifically, the control device 50 determines the resonant frequency fc of the piezoelectric element 14 as the driving frequency, and drives the piezoelectric element 14 at the determined driving frequency. In the drive mode, the cleaning solution may be ejected from the cleaning nozzle 3 illustrated in FIG. 1 in conjunction with the vibration of the piezoelectric element 14 to remove the foreign matter adhering to the light-transmitting body 2.

In step S6, when it is determined that the measured impedance value Z is not equal to or less than the threshold value Zth, the control device 50 updates the frequency fr of the drive signal to fr+Δf (step S9). For example, Δf is 1 Hz or more and 1 kHz or less.

Next, the control device 50 determines whether or not the frequency fr of the drive signal exceeds the frequency fmax (step S10). For example, the frequency fmax is 1 MHz or less.

In step S10, when it is determined that the frequency fr of the drive signal does not exceed the frequency fmax, the process returns to step S4.

The above steps S1 to S10 constitute the first search step. In step S10, when it is determined that the frequency fr of the drive signal exceeds the frequency fmax, the following second search step is performed.

In step S10, when it is determined that the frequency fr of the drive signal exceeds the frequency fmax, the control device 50 changes the voltage waveform of the driving voltage Vpp. As a result, the voltage waveform of the drive signal applied to the piezoelectric element 14 is changed. For example, the effective voltage of the voltage waveform is changed. For example, the amplitude of the voltage waveform is changed. In addition, for example, the amplitude of the voltage waveform is increased. In addition, for example, the amplitude of the voltage waveform is decreased. Specifically, the driving voltage Vpp is updated to Vpp+ΔV (step S11). AV may be a positive value or a negative value. That is, the amplitude of the voltage waveform applied to the piezoelectric element 14 is increased or decreased. For example, the absolute value of ΔV is greater than 0 V and 70 V or less.

Next, the control device 50 updates the number of update times Nv of the driving voltage Vpp to Nv+1 (step S12).

Next, the control device 50 determines whether or not the number of update times Nv updated in step S12 exceeds the maximum number of update times Nvmax (step S13). The maximum number of update times Nvmax may be the number of times determined in advance. For example, Nvmax is one time or more and 10 times or less.

When it is determined in step S13 that the number of update times Nv exceeds Nvmax, the control device 50 detects an error (ERROR) (step S14) and ends the operation in the search mode (step S15).

When it is determined in step S13 that the number of update times Nv does not exceed Nvmax, the process returns to step S3.

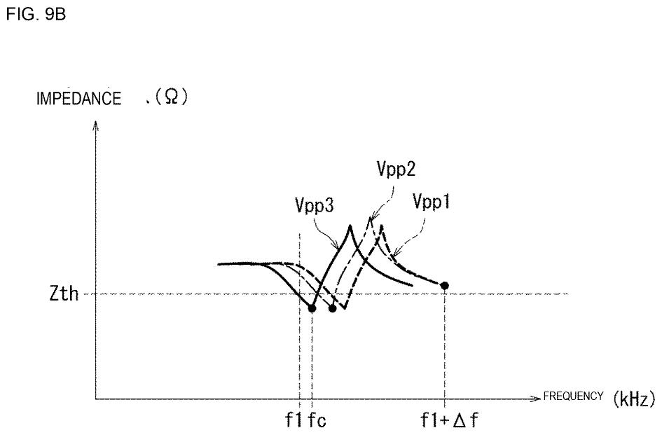

Here, a relationship between the resonant frequency and the impedance of the piezoelectric element 14 when the effective voltage of the driving voltage Vpp is changed will be described with reference to FIGS. 9A and 9B. In FIG. 9A, the horizontal axis represents the effective voltage (V), and the vertical axis represents the resonant frequency (Hz). FIG. 9A illustrates an example of a change in the resonant frequency fc of the piezoelectric element 14 when the effective voltage is changed from 10 V to 50 V in increments of 10. As is clear from the graph illustrated in FIG. 9A, the resonant frequency fc of the piezoelectric element 14 decreases as the effective voltage increases. In FIG. 9B, the horizontal axis represents the frequency (kHz), and the vertical axis represents the impedance (Ω). The graph illustrated in FIG. 9B illustrates a state of a change in the resonant frequency in a case where the effective voltage is changed from Vpp1 to Vpp3. In the effective voltage illustrated in FIG. 9B, Vpp1>Vpp2>Vpp3. The frequency f1 of FIG. 9B is an example of the frequency fr of the drive signal in which fmin≤f1≤fmax. From the graph of FIG. 9B, in a case where the effective voltage is Vpp1 and Vpp2, in the drive signal of the frequency f1 or the frequency f1+Δf, the impedance value Z is greater than the threshold value Zth, and the resonant frequency fc cannot be searched for. However, in a case where the effective voltage is Vpp3, the frequency at which the impedance value Z is equal to or less than the threshold value Zth can be searched for by the drive signal having the frequency f1. That is, by changing the driving voltage Vpp to Vpp+ΔV in step S11 and further performing steps after step S3, the resonant frequency fc of the piezoelectric element 14 can be matched the frequency fr of the drive signal or can be close to the frequency fr of the drive signal.

Therefore, by performing the second search step of the above control method, the search performance of the resonant frequency fc of the piezoelectric element 14 can be improved. In addition, in the above-described control method, the search performance of the resonant frequency can be improved without changing the performance of the processor 20, and the manufacturing cost can be reduced.

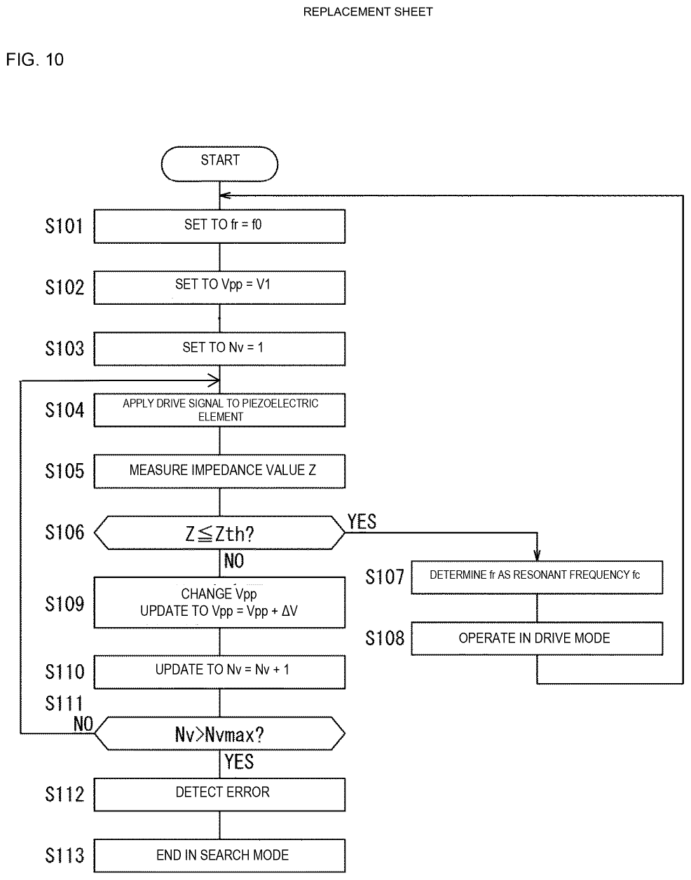

In an aspect of the present disclosure, the second search step is performed after the first search step is performed, but the first search step can be omitted. The operation of the vibration device 10 of the imaging unit 100 in the present modification example will be described with reference to FIG. 10. FIG. 10 is a flowchart describing an operation of a control device that controls a vibration device according to the present modification example.

First, the control device 50 sets the frequency fr of the drive signal to f0 (step S101). For example, f0 is any resonant frequency searched for in a preceding search mode.

Next, the control device 50 sets the driving voltage Vpp to V1 (step S102) and sets the number of update times Nv of the driving voltage Vpp to 1 (step S103).

Next, the control device 50 applies the drive signal of the frequency fr set in step S101 and the driving voltage Vpp set in step S102 to the piezoelectric element 14 (step S104).

Next, the control device 50 measures the impedance value Z of the piezoelectric element 14 at the frequency fr of the drive signal (step S105).

Next, the control device 50 determines whether or not the measured impedance value is equal to or less than the predetermined threshold value Zth (step S106).

When it is determined that the impedance value Z measured in step S106 is equal to or less than the predetermined threshold value Zth, the control device 50 determines the frequency fr of the drive signal as the resonant frequency fc of the piezoelectric element 14 (step S107).

After step S107, the control device 50 operates in a drive mode of removing the foreign matter adhering to the light-transmitting body 2 by causing the piezoelectric element 14 to vibrate at the resonant frequency fc (step S108). Specifically, the control device 50 determines the resonant frequency fc of the piezoelectric element 14 as the driving frequency, and drives the piezoelectric element 14 at the determined driving frequency. In the drive mode, the cleaning solution may be ejected from the cleaning nozzle 3 illustrated in FIG. 1 in conjunction with the vibration of the piezoelectric element 14 to remove the foreign matter adhering to the light-transmitting body 2.

In step S106, when it is determined that the impedance value Z exceeds the predetermined threshold value Zth, the control device 50 updates the driving voltage Vpp to Vpp+ΔV (step S109).

Next, the control device 50 updates the number of update times Nv of the driving voltage Vpp to Nv+1 (step S110).

Next, the control device 50 determines whether or not the number of update times Nv updated in step S110 exceeds the maximum number of update times Nvmax (step S111).

When it is determined in step S111 that the number of update times Nv exceeds Nvmax, the control device 50 detects an error (ERROR) (step S112) and ends the operation in the search mode (step S113).

When it is determined in step S111 that the number of update times Nv does not exceed Nvmax, the process returns to step S104.

In the above control method, the search performance of the resonant frequency fc of the piezoelectric element 14 can be improved. In addition, the above-described control method can simplify the control step and can shorten the time of the frequency search.

In the above-described control method, the control device 50 detects the impedance value Z of the piezoelectric element 14, but the control device 50 may detect the current value I of the piezoelectric element 14.

Since the current value is the reciprocal of the impedance, in a case where the control device 50 detects the current value I of the piezoelectric element 14, the current value I is measured in step S5 of the above control method, and it is determined in step S6 whether or not the current value I is greater than a predetermined threshold value Ith.

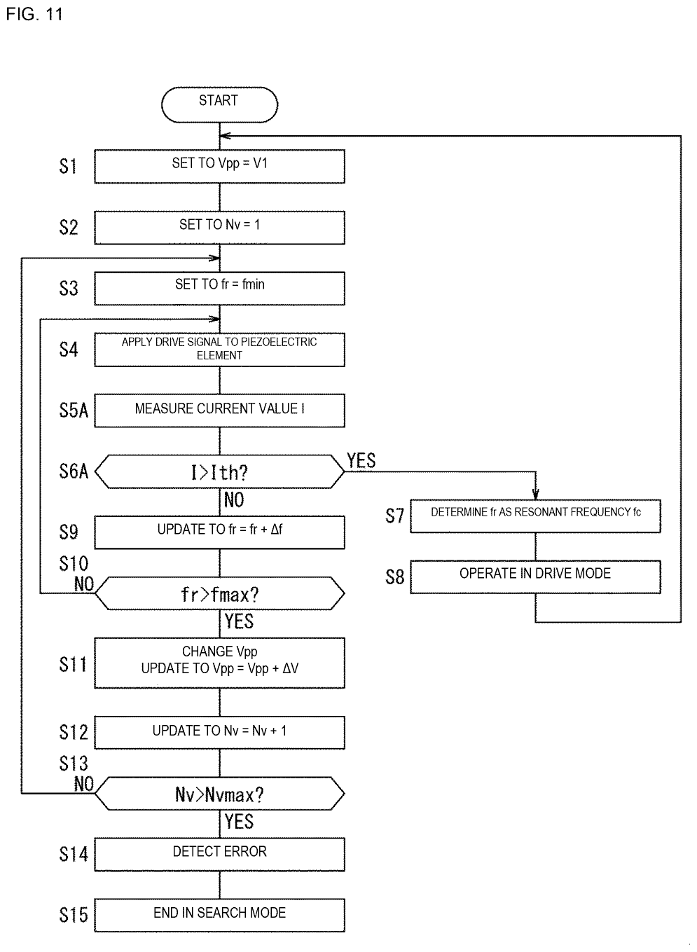

FIG. 11 illustrates a flowchart describing an operation of a control device that controls a vibration device according to the present modification example.

First, steps S1 to S4 of an aspect as illustrated in FIG. 7 are performed.

Next, the current value I of the piezoelectric element 14 is measured via the control device 50 (step S5A).

Next, the control device 50 determines whether or not the current value I measured in step S5A is greater than the predetermined threshold value Ith (step S6A).

In step S6A, when it is determined that the current value I is greater than the predetermined threshold value Ith, step S7 and step S8 of an aspect illustrated in FIG. 7 are performed.

In step S6A, when it is determined that the current value I is not greater than the predetermined threshold value Ith, step S9 to step S15 of an aspect illustrated in FIG. 7 are performed.

According to the above-described control method, the driving frequency for driving the piezoelectric element 14 can be appropriately controlled. Specifically, since the search performance of the resonant frequency of the piezoelectric element 14 can be improved, the driving frequency can be appropriately determined. In addition, in the above-described control method, since the measured value for determining the resonant frequency fc of the piezoelectric element 14 is the current value I of the piezoelectric element 14, the measurement is easy.

An aspect of the present disclosure is different from an aspect described above in that the method of searching for the resonant frequency in the search mode is different. The search mode in an aspect includes a first search step and a third search step. The first search step is different from an aspect described above in that the frequency fr of the drive signal is swept between fmin and fmax to search for the resonant frequency fc of the piezoelectric element 14. The third search step is performed in a case where the resonant frequency fc of the piezoelectric element 14 cannot be searched for in the first search step. In the third search step, the resonant frequency fc of the piezoelectric element 14 is searched for by changing the clock width of some clocks among the plurality of clocks included in the drive signal. Here, the change in the clock width may be performed by changing the duty ratio.

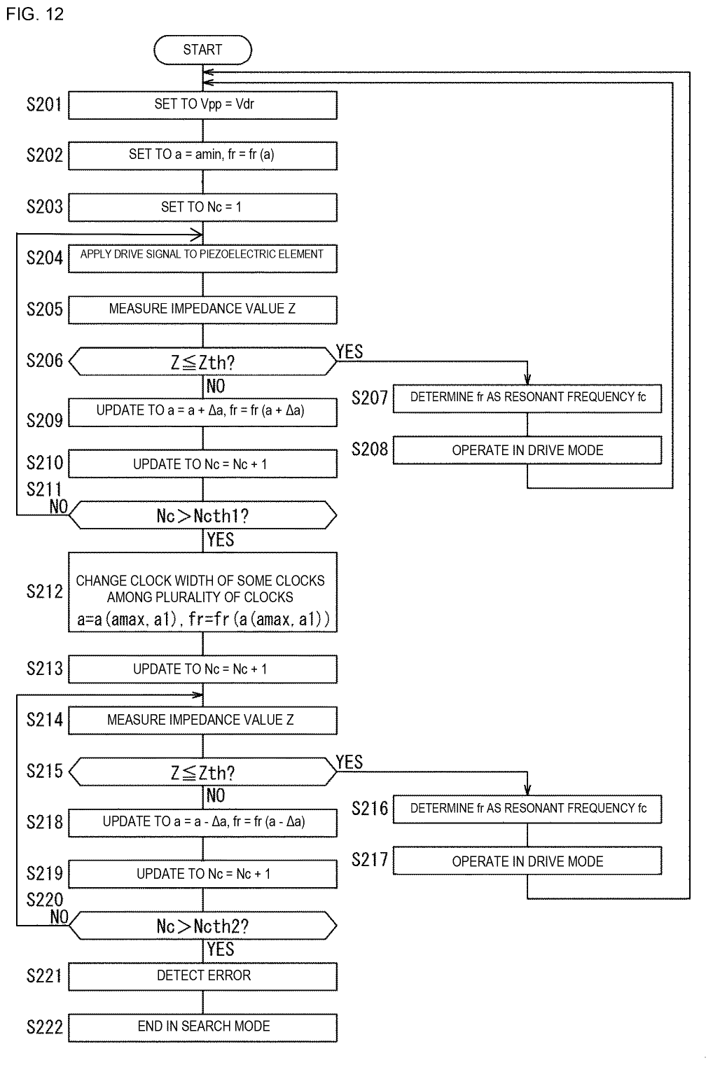

FIG. 12 is a flowchart describing an operation of a control device that controls a vibration device according to an aspect of the present disclosure. A control method of the vibration device in an aspect will be described with reference to FIG. 12.

First, the control device 50 sets the driving voltage Vpp to Vdr (step S201). For example, the effective voltage of the voltage Vdr is 0 V or more and 70 V or less.

Next, the control device 50 sets a clock width a of the plurality of clocks included in the drive signal to amin (step S202), and sets the number of update times Nc of the clock width a to 1 (step S203). amin is the minimum value of the clock width a, and is, for example, a value set in advance. For example, amin is 1 μsec (1 MHz) or more and 50 μsec (20 kHz) or less. Here, since the frequency fr of the drive signal depends on the clock width, when the clock width a is set, the frequency fr of the drive signal is set to fr (a). In addition, in a case where the clock widths of the plurality of clocks are the single width a, fr=fr (a)=a. Therefore, when the clock width a is set to amin, the frequency fr is set to fr (a)=amin=fmin.

Next, the control device 50 applies the driving voltage Vpp set in step S201 and the drive signal of the frequency fr set in step S202 to the piezoelectric element 14 (step S204).

Next, the control device 50 measures the impedance value Z of the piezoelectric element 14 at the frequency fr of the drive signal (step S205).

The control device 50 determines whether or not the measured impedance value Z is equal to or less than the predetermined threshold value Zth (step S206).

When it is determined in step S206 that the measured impedance value Z is equal to or less than the threshold value Zth, the control device 50 determines the frequency fr of the drive signal as the resonant frequency fc of the piezoelectric element 14 (step S207).

After step S207, the control device 50 operates in a drive mode of removing the foreign matter adhering to the light-transmitting body 2 by causing the piezoelectric element 14 to vibrate at the resonant frequency fc determined in step S207 (step S208). In the drive mode, the cleaning solution may be ejected from the cleaning nozzle 3 illustrated in FIG. 1 in conjunction with the vibration of the piezoelectric element 14 to remove the foreign matter adhering to the light-transmitting body 2.

When it is determined that the measured impedance value Z in step S206 is not equal to or less than the threshold value Zth, the control device 50 updates the clock width a of the plurality of clocks included in the drive signal to a+Δa (step S209). As a result, the frequency fr of the drive signal is updated to fr (a+Δa)=a+Δa. For example, Δa is 1 Hz or more and 1 kHz or less.

Next, the control device 50 updates the number of update times Nc of the clock width a to Nc+1 (step S210).

Next, the control device 50 determines whether or not the number of update times Nc updated in step S210 exceeds a predetermined threshold value Ncth1 (step S211). For example, Ncth1 is one time or more and 10 times or less.

When it is determined in step S211 that the number of update times Nc does not exceed Ncth1, the process returns to step S203.

Steps S201 to S211 are the first search step in an aspect, and when it is determined in step S211 that the number of update times Nc exceeds Ncth1, the frequency fr of the drive signal has reached fmax. Therefore, in the first search step, the frequency fr of the drive signal is swept from fmin to fmax. That is, in the first search step, the clock width is changed from amin to amax. In step S211, when it is determined that the number of update times Nc exceeds Ncth1, the following third search step is performed.

When it is determined in step S211 that the number of update times Nc exceeds Ncth1, the control device 50 changes the clock width such that the clock width of some clocks among the plurality of clocks and the clock width of the other clocks are different from each other (step S212). In other words, some clocks are referred to as a plurality of first clocks, and the remaining clocks are referred to as a plurality of second clocks, and the clock width of the plurality of first clocks is maintained at amax, and the clock width of the plurality of second clocks is changed to a1. For example, the clock width a1 is a value of less than one time the clock width amax, preferably a value of 0.5 times or more and less than one time the clock width amax, and more preferably a value of 0.99 times or more and less than one time the clock width amax. That is, the control device 50 changes the clock width of some clocks among the plurality of clocks to a value less than one time the clock width of the other clocks, preferably to a value of 0.5 times or more and less than one time the clock width of the other clocks, and more preferably to a value of 0.99 times or more and less than one time the clock width of the other clocks. In addition, for example, the width a1 is amax−Δa, and for example, Δa is the same as Δa in step S209. With the change in the clock width a, the frequency fr of the drive signal is changed to fr (a(amax, a1)). In accordance with an aspect of the present disclosure, widths of the plurality of second clocks among the plurality of clocks are set to be less than one time widths of the plurality of first clocks, but the present disclosure is not limited to this, and widths of the plurality of second clocks among the plurality of clocks may be set to be greater than one time widths of the plurality of first clocks. In this case, for example, widths of the plurality of second clocks are greater than one time and 1.5 times or less widths of the plurality of first clocks, and preferably greater than one time and 1.01 times or less widths of the plurality of first clocks.

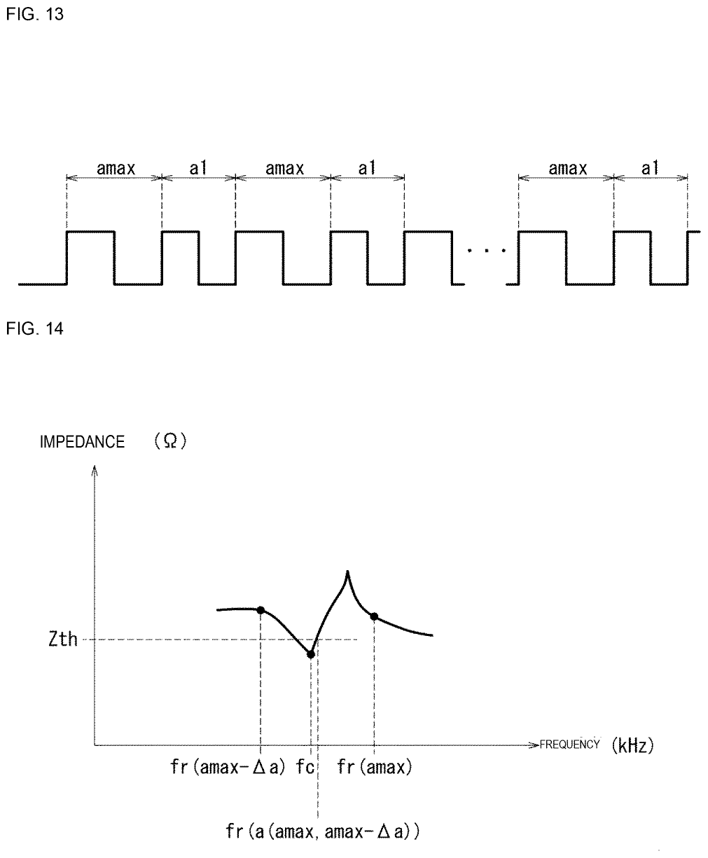

In addition, in step S212, the control device 50 changes the clock width of the clock of, for example, 0.1% or more and 99.9% or less among the plurality of clocks included in the drive signal. A specific example will be described with reference to FIG. 13. FIG. 13 illustrates an example of a plurality of clocks included in a drive signal in which the clock width is changed. As illustrated in FIG. 13, the control device 50 changes the clock width of ½ (50%) of the plurality of clocks included in the drive signal to the width amax, and changes the clock width of the remaining ½ (50%) of the clocks to the width a1.

In addition, in step S212, the control device 50 periodically changes the clock width of the plurality of clocks, for example. As a result, some clocks are periodically located in the plurality of clocks. For example, some clocks are located at equal intervals in the plurality of clocks. Specifically, the control device 50 periodically changes the clock widths of the plurality of clocks such that the clock having the width amax and the clock having the width a1 among the plurality of clocks included in the drive signal are alternately included.

Next, the control device 50 updates the number of update times Nc of the clock width a to Nc+1 (step S213).

Next, the control device 50 measures the impedance value Z of the piezoelectric element 14 at the frequency fr (a(amax, a1)) of the drive signal (step S214).

Next, the control device 50 determines whether or not the impedance value Z measured in step S214 is equal to or less than the predetermined threshold value Zth (step S215).

When it is determined that the impedance value Z measured in step S215 is equal to or less than the predetermined threshold value Zth, the control device 50 determines the frequency fr of the drive signal as the resonant frequency fc of the piezoelectric element 14 (step S216).

After step S216, the control device 50 operates in a drive mode of removing the foreign matter adhering to the light-transmitting body 2 by causing the piezoelectric element 14 to vibrate at the resonant frequency fc determined in step S216 (step S217). Specifically, the control device 50 determines the resonant frequency fc of the piezoelectric element 14 as the driving frequency, and drives the piezoelectric element 14 at the determined driving frequency. In the drive mode, the cleaning solution may be ejected from the cleaning nozzle 3 illustrated in FIG. 1 in conjunction with the vibration of the piezoelectric element 14 to remove the foreign matter adhering to the light-transmitting body 2.

In step S215, when it is determined that the measured impedance value Z is not equal to or less than the threshold value Zth, the control device 50 updates the clock width of the plurality of clocks included in the drive signal to a clock width a−Δa (step S218). As a result, the frequency fr of the drive signal is updated to fr (a−Δa). The update to the clock width a−Δa means, for example, that both the clock width amax and the clock width a1 are decreased by Δa. For example, Δa is the same as Δa in step S209.

Next, the control device 50 updates the number of update times Nc of the clock width a to Nc+1 (step S219).

Next, the control device 50 determines whether or not the number of update times Nc updated in step S219 exceeds the threshold value Ncth2 (step S220). For example, Ncth2 is one time or more and 10 times or less.

When it is determined in step S220 that the number of update times Nc does not exceed Ncth2, the process returns to step S214.

When it is determined in step S220 that the number of update times Nc exceeds Ncth2, the control device 50 detects an error (ERROR) and ends the operation in the search mode (step S221).

When the plurality of clocks included in the drive signal include two or more clock widths, the frequency fr of the drive signal is the frequency fr depending on the two or more clock widths. For example, when the plurality of clocks included in the drive signal include the clock having the clock width A1 at a ratio of N1% and the clock having the clock width A2 at a ratio of N2% (N2=100−N1), the frequency fr of the drive signal is represented by Equation 1.

$$fr = fr ( a ( A 1 , A 2 ) ) = N 1 / 100 \times A 1 + N 2 / 100 \times A 2 = N 1 / 100 \times fr ( A 1 ) + N 2 / 100 \times fr ( A 2 ) \qquad ( Equation 1 )$$

Specifically, for example, in a case where the plurality of clocks included in the drive signal include the clock having the clock width amax at a ratio of 50% and the clock having the clock width a1=amax−Δa at a ratio of 50%, the frequency fr of the drive signal is represented by Equation 2.

$$fr = fr ( a ( a max , a 1 ) ) = fr ( a ( a max , a max - Δ a ) ) = 50 / 100 \times a max + 50 / 100 \times ( a max - Δ a ) = 1 / 2 \times a max + 1 / 2 \times ( a max - Δ a ) = 1 / 2 \times fr ( a max ) + 1 / 2 \times fr ( a max - Δ a ) \qquad ( Equation 2 )$$

Therefore, by performing the third search step, the drive signal having the frequency fr of the value between fr (amax) and fr (amax−Δa) can be emitted.

Here, a description will be made with reference to FIG. 14. FIG. 14 illustrates a relationship between a frequency of the drive signal and a resonant frequency in a graph illustrating a relationship between a resonant frequency and an impedance of the piezoelectric element. In the graph illustrated in FIG. 14, the horizontal axis represents the frequency (kHz), and the vertical axis represents the impedance (Ω). In the example illustrated in FIG. 14, the resonant frequency fc of the piezoelectric element 14 is present between fr (amax) and fr (amax−Δa). In addition, when the frequency fr of the drive signal is fr (amax) or fr (amax−Δa), the measured impedance Z is greater than the threshold value Zth. Therefore, the resonant frequency fc cannot be searched for in the first search step. However, as illustrated in Equation 2, by performing the third search step, the drive signal having the frequency fr (a(amax, amax−Δa)) of the value between fr (amax) and fr (amax−Δa) can be emitted. As a result, the resonant frequency fc that cannot be searched for in the first search step and that is present between the fr (amax) and the fr (amax−Δa) can be searched for.

Therefore, with the third search step of the control method described above, the frequency resolution can be improved regardless of the performance of the processor 20. As a result, the driving frequency of the piezoelectric element 14 can be appropriately controlled. Specifically, since the search performance of the resonant frequency fc of the piezoelectric element 14 can be further improved, the driving frequency of the piezoelectric element 14 can be appropriately determined. In addition, since the expensive processor 20 need not be used, an increase in manufacturing cost can be reduced.

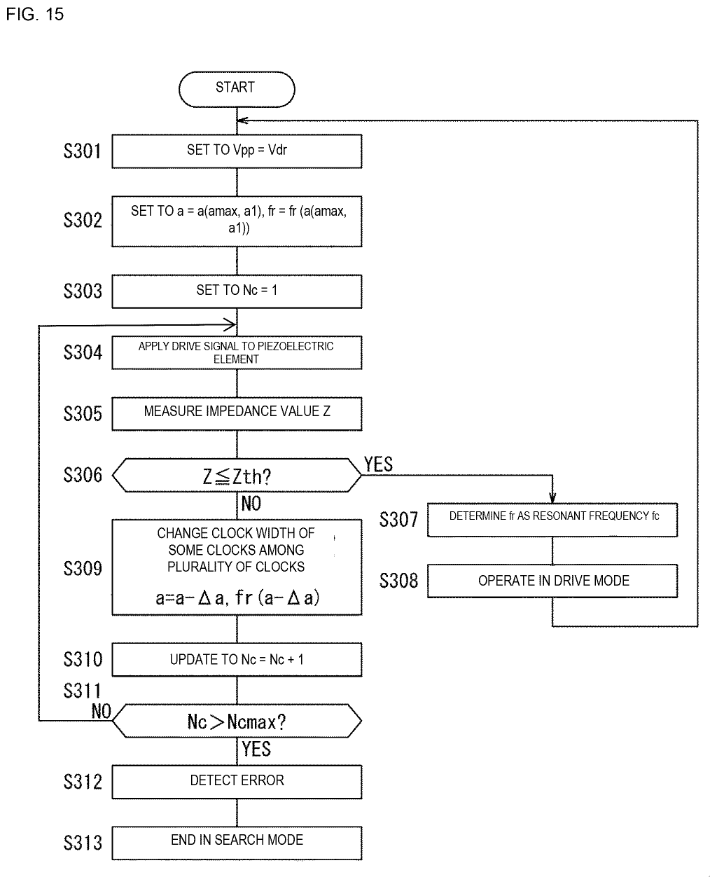

In a control method of an aspect of the present disclosure, the third search step is performed after the first search step is performed, but the first search step can be omitted. The operation of the vibration device 10 of the imaging unit 100 in the present modification example will be described with reference to FIG. 15. FIG. 15 is a flowchart describing an operation of a control device that controls a vibration device according to the present modification example.

First, the control device 50 sets the driving voltage Vpp to Vdr (step S301).

Next, the control device 50 sets the clock width such that the clock width of some clocks among the plurality of clocks is different from the clock width of the other clocks (step S302). For example, the clock width of 50% of the plurality of clocks included in the drive signal is set to the width amax, and the clock width of the remaining 50% of the clocks is set to the width a1. For example, the width a1 is amax−Δa, and for example, Δa is the same as Δa in step S209 of an aspect of the present disclosure. With the change in the clock width, the frequency fr of the drive signal is set to fr (a(amax, a1)).

In addition, in step S302, as the method in which the clock width of some clocks among the plurality of clocks and the clock width of the other clocks are different from each other, the control device 50 can adopt the same method as the method of changing the clock width in step S212 of an aspect of the present disclosure.

Next, the control device 50 sets the number of update times Nc of the clock width a to 1 (step S303).

Next, the control device 50 applies the driving voltage Vpp set in step S301 and the drive signal of the frequency fr (a(amax, a1)) set in step S302 to the piezoelectric element 14 (step S304).

Next, the control device 50 measures the impedance value Z of the piezoelectric element 14 at the frequency fr (a(amax, a1)) of the drive signal (step S305).

Next, the control device 50 determines whether or not the impedance value Z measured in step S305 is equal to or less than the predetermined threshold value Zth (step S306).

When it is determined that the impedance value Z measured in step S305 is equal to or less than the threshold value Zth, the control device 50 determines the frequency fr of the drive signal as the resonant frequency fc of the piezoelectric element 14 (step S307).

After step S307, the control device 50 operates in the drive mode of removing the foreign matter adhering to the light-transmitting body 2 by vibrating the piezoelectric element 14 at the resonant frequency fc determined in step S407 (step S308). In the drive mode, the cleaning solution may be ejected from the cleaning nozzle 3 in conjunction with the vibration of the piezoelectric element 14 to remove the foreign matter adhering to the light-transmitting body 2.

In step S306, when it is determined that the measured impedance value Z is not equal to or less than the threshold value Zth, the control device 50 updates the clock width of the plurality of clocks included in the drive signal to a clock width a−Δa (step S309). As a result, the frequency fr of the drive signal is updated to fr (a−Δa). The update to the clock width a−Δa means, for example, that both the clock width amax and the clock width a1 are decreased by Δa. For example, Δa is the same as Δa in step S209 of an aspect.

Next, the control device 50 updates the number of update times Nc of the clock width a to Nc+1 (step S310).

Next, the control device 50 determines whether or not the number of update times Nc updated in step S410 exceeds Ncmax (step S311). The maximum number of update times Ncmax may be the number of update times set in advance. For example, Ncmax is one time or more and 10 times or less.

When it is determined in step S311 that the number of update times Nc does not exceed Ncmax, the process returns to step S305.

When it is determined in step S311 that the number of update times Nc exceeds Ncmax, the control device 50 detects an error (ERROR) (step S312) and ends the operation in the search mode (step S313).

In the above control method, the search performance of the resonant frequency fc of the piezoelectric element 14 can be improved. In addition, the above-described control method can simplify the control and can shorten the time of the frequency search.

In the control method of an aspect of the present disclosure, in step S212, the control device 50 maintains the clock width of ½ (50%) of the plurality of clocks included in the drive signal at the width amax, and changes the clock width of the remaining ½ (50%) of the clocks to the width a1. However, the method in which the processor 20 changes the clock width such that the clock width of some clocks among the plurality of clocks and the clock width of the other clocks are different from each other is not limited thereto.

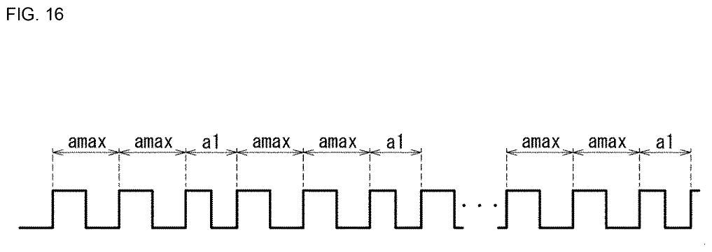

For example, as illustrated in FIG. 16, the control device 50 may maintain the clock width of ⅔ of the plurality of clocks included in the drive signal at the width amax, and may change the clock width of the remaining ⅓ of the clocks to a width a1. In this case, the clock having the clock width a1 is emitted, for example, in one period every three times. In addition, in this case, the frequency fr of the drive signal is represented by Equation 3.

$$fr = fr ( a ( a max , a 1 ) ) = fr ( a ( a max , a max - Δ a ) ) = 2 / 3 \times a max + 1 / 3 \times ( a max - Δ a ) = 2 / 3 \times fr ( a max ) + 1 / 3 \times fr ( a max - Δ a ) \qquad ( Equation 3 )$$

That is, the drive signal having a frequency fr different from the drive signal that includes the clock having the width amax at a ratio of ⅔ and the clock having the clock width a1 at a ratio of ⅓ and the drive signal that includes the clock having the width amax and the clock having the width a1 at the same ratio can be emitted.

From the above configurations, the drive signal can be emitted having various frequencies fr according to the method of changing the clock width of the plurality of clocks included in the drive signal. As a result, the driving frequency of the piezoelectric element 14 can be appropriately controlled. Specifically, since the drive signal having a desired frequency can be emitted and the search performance of the resonant frequency fc can be improved, the driving frequency of the piezoelectric element 14 can be appropriately determined.

In the above-described aspects, the example is described in which the control device 50 determines the resonant frequency of the piezoelectric element 14 and sets the determined resonant frequency as the driving frequency for driving the piezoelectric element 14, but the present disclosure is not limited thereto. For example, the control device 50 may determine the driving frequency based on a change in the value related to the impedance of the piezoelectric element 14 without determining the resonant frequency of the piezoelectric element 14.

The control method of controlling the vibration device of the present disclosure and the control device of the vibration device can be applied to a vibration device used in an in-vehicle camera, a surveillance camera, or an optical sensor such as LiDAR used outdoors.

In general, the description of the aspects disclosed should be considered as being illustrative in all respects and not being restrictive. The scope of the present disclosure is shown by the claims rather than by the above description, and is intended to include meanings equivalent to the claims and all changes in the scope. While preferred aspects of the invention have been described above, it is to be understood that variations and modifications will be apparent to those skilled in the art without departing from the scope and spirit of the invention.

### DESCRIPTION OF REFERENCE SYMBOLS

1 housing
2 light-transmitting body
3 cleaning nozzle
5 imaging device
10 vibration device
12 vibration body
13 retainer
14 piezoelectric element
15 wiring
20 processor
30 piezoelectric driving unit
50 control device
70 impedance detection unit
80 power supply circuit
100 imaging unit

1. A method of controlling a vibration device including a piezoelectric element via a control device, the method comprising:
changing a frequency of a drive signal for driving the piezoelectric element;
measuring a value related to an impedance of the piezoelectric element; and
determining a driving frequency for driving the piezoelectric element based on the measured value related to the impedance of the piezoelectric element,
wherein the changing of the frequency of the drive signal includes changing a clock width such that a clock width of a first portion of clocks among a plurality of clocks included in the drive signal and a clock width of a second portion of clocks among the plurality of clocks are different from each other.

2. The method according to claim 1, wherein the first portion of clocks are periodically located in the plurality of clocks.

3. The method according to claim 1, wherein the first portion of clocks are located at equal intervals in the plurality of clocks.

4. The method according to claim 1, wherein, among the plurality of clocks, the clock width of the first portion of clocks is 0.5 times or more and less than one time or greater than one time and 1.5 times or less the clock width of the second portion of clocks among the plurality of clocks.

5. The method according to claim 1, wherein a clock width of a clock of 0.1% or more and 99.9% or less among the plurality of clocks is changeable.

6. The method according to claim 1,
wherein the value related to the impedance is an impedance value, and
wherein the determining of the driving frequency includes:
determining when the value related to the impedance is equal to or less than a predetermined threshold value, and
determining the frequency of the drive signal, when the value related to the impedance is determined to be equal to or less than the predetermined threshold value, as the driving frequency.

7. The method according to claim 1, further comprising changing the clock width, when the driving frequency is not determined based on the value related to the impedance measured after the clock width is changed, in the determining of the driving frequency.

8. The method according to claim 1, wherein the changing of the frequency of the drive signal includes changing the frequency while keeping constant clock widths of the plurality of clocks.

9. The method according to claim 8, wherein the measuring of the value related to the impedance includes measuring the value related to the impedance while changing the frequency with the clock width being kept constant.

10. The method according to claim 9, wherein the determining of the driving frequency, when the driving frequency is not determined based on the value related to the impedance measured while changing the frequency with the clock width being kept constant, includes changing the clock width.

11. A control device that controls a vibration device including a piezoelectric element, the control device comprising:
a processor; and
a memory that stores a command executed by the processor, causing the processor to:
change a frequency of a drive signal transmitted from the processor to the piezoelectric element,
measure a value related to an impedance of the piezoelectric element,
determine a driving frequency for driving the piezoelectric element based on the measured value related to the impedance of the piezoelectric element, and
change the frequency of the drive signal by changing a clock width such that a clock width of a first portion of clocks among a plurality of clocks included in the drive signal and a clock width of a second portion of clocks among the plurality of clocks are different from each other.

12. The control device according to claim 11, wherein the first portion of clocks are periodically located in the plurality of clocks.

13. The control device according to claim 11, wherein the first portion of clocks are located at equal intervals in the plurality of clocks.

14. The control device according to claim 11, wherein, among the plurality of clocks, the clock width of the first portion of clocks is 0.5 times or more and less than one time or greater than one time and 1.5 times or less the clock width of the second portion of clocks.

15. The control device according to claim 11, wherein a clock width of a clock of 0.1% or more and 99.9% or less among the plurality of clocks is changeable.

16. The control device according to claim 11,
wherein the value related to the impedance is an impedance value, and
the processor determines the driving frequency by:
determining when the value related to the impedance is equal to or less than a predetermined threshold value, and
determining a frequency of the drive signal, when it is determined that the value related to the impedance is equal to or less than the predetermined threshold value, as the driving frequency.

17. The control device according to claim 11, wherein the processor changes the clock width, when the driving frequency is not determined based on the value related to the impedance measured after the clock width is changed, in determining the driving frequency.

18. The control device according to claim 11, wherein the processor changes the frequency of the drive signal by changing the frequency while keeping constant clock widths of the plurality of clocks.

19. The control device according to claim 18, wherein the processor measures the value related to the impedance includes by measuring the value related to the impedance while changing the frequency with the clock width being kept constant.

20. The control device according to claim 19, wherein, when the driving frequency is not determined based on the value related to the impedance measured while changing the frequency with the clock width being kept constant, the determines the driving frequency while changing the clock width.
